(19) United States
(12) Patent Application Publication
(10) Pub. No.: US 2012/0061842 A1
(43) Pub. Date: Mar. 15, 2012

(54) STACK PACKAGE AND METHOD FOR MANUFACTURING THE SAME

(75) Inventor: Seong Cheol KIM, Anseong-si (KR)

(73) Assignee: HYNIX SEMICONDUCTOR INC., Icheon-si (KR)

(21) Appl. No.: 13/228,560

(22) Filed: Sep. 9, 2011

(30) Foreign Application Priority Data
Sep. 13, 2010 (KR) 10-2010-0089595

(51) Int. Cl. H01L 23/538; H01L 21/50

(52) U.S. Cl. 257/769; 257/774; 257/741; 257/768; 257/770; 438/107; 257/E23.003; 257/E23.174; 257/E21.499

(57) ABSTRACT

A stack package includes a substrate, a lower semiconductor chip stacked on the substrate and electrically connected to the substrate through a lower via, a plurality of upper semiconductor chips stacked on the lower semiconductor chip and electrically connected to the lower via through an upper via, wherein the upper semiconductor chips are larger in size than the lower semiconductor chip, and an edge guide electrically connecting edge vias of the upper semiconductor chips and the substrate.

### CROSS-REFERENCES TO RELATED APPLICATIONS

The present application claims priority under 35 U.S.C 119(a) to Korean Application No. 10-2010-0089595, filed on Sep. 13, 2010, in the Korean intellectual property Office, which is incorporated herein by reference in its entirety set forth in full.

### BACKGROUND

Exemplary embodiments of the present invention relate to a stack package and a method for manufacturing the same, and more particularly, to a stack package in which semiconductor chips having different sizes are stacked, and a method for manufacturing the same.

As the demands for small-sized, high-performance and mobile electronic products increase, ultra-small high-capacity semiconductor memory devices are being increasingly demanded. In general, the storage capacity of the semiconductor memory device may be increased by a method of increasing the integration degree of a semiconductor chip, or a method of mounting and assembling a plurality of semiconductor chips within a single semiconductor package. Here, the latter method may be advantageous in terms of a cost, research and development effort, and development time, as compared to the former method. Hence, semiconductor memory manufacturers are making many efforts to increase the storage capacity of the semiconductor memory device through a multi chip package which mounts the plurality of semiconductor chips within the single semiconductor package.

Examples of the method of mounting the plurality of semiconductor chips within the single semiconductor package include a method of mounting semiconductor chips horizontally, and a method of mounting semiconductor chips vertically. However, due to a miniaturization of electronic products, most semiconductor memory manufacturers prefer a stack type multi chip package in which semiconductor chips are stacked vertically.

A stack chip package technique can reduce a manufacturing cost of a package due to a simplified process and is advantageous to mass production. However, the stack chip package technique may have a disadvantage in that an interconnection space for internal electrical connection of the package is insufficient due to increase in the number and size of stacked chips. That is, in such a state that a plurality of chips are attached to chip attachment regions of a substrate, a known stack chip package is manufactured in a structure in which a bonding wire of each chip and a conductive circuit pattern of a substrate are electrically connected by a wire. Thus, a space for wire bonding is required, and also a circuit pattern area for wire connection is required. Consequently, a size of a semiconductor package may increase.

Considering these points, a package structure using a through-silicon via (TSV) has been proposed as an example of a stack package. Such a package is manufactured by forming TSVs through chips at a wafer level and connecting the chips physically and electrically in a vertical direction by the TSVs.

In a case that semiconductor chips to be mounted within the single semiconductor package have different sizes, there has been proposed a method which expands the size of the smallest semiconductor chip to the size of the largest semiconductor chip. However, such a method unnecessarily expands the semiconductor chip having a small size. Consequently, productivity of the stack package may decrease, and a probability of formation of voids may increase during a gap-fill process.

### SUMMARY

An embodiment of the present invention is directed to a stack package, which can efficiently stack semiconductor chips having different sizes, and a method for manufacturing the same.

In an exemplary embodiment of the present invention, a stack package includes a substrate, a lower semiconductor chip stacked on the substrate and electrically connected to the substrate through a lower via, a plurality of upper semiconductor chips stacked on the lower semiconductor chip and electrically connected to the lower via through an upper via, wherein the upper semiconductor chips are larger in size than the lower semiconductor chip, and an edge guide electrically connecting edge vias of the upper semiconductor chips and the substrate.

In another exemplary embodiment of the present invention, a method for manufacturing a stack package includes stacking a lower semiconductor chip on a substrate, wherein the lower semiconductor chip is electrically connected to the substrate through a lower via, stacking upper semiconductor chips on the lower semiconductor chip, wherein the upper semiconductor chips are larger in size than the lower semiconductor chip and are electrically connected to the lower via through an upper via, and forming an edge guide which electrically connects edge vias of the upper semiconductor chips and the substrate.

According to the embodiments of the present invention, semiconductor chips having different sizes can be efficiently stacked. Hence, the miniaturization and lightweight of the package may be achieved, and a probability of formation of gap-fill void may decrease.

### BRIEF DESCRIPTION OF THE DRAWINGS

The above and other aspects, features and other advantages will be more clearly understood from the following detailed description taken in conjunction with the accompanying drawings, in which:

FIG. 1 is a cross-sectional view of a stack package according to an exemplary embodiment of the present invention;

FIGS. 2A to 2E are cross-sectional views illustrating a method for manufacturing a stack package according to another exemplary embodiment of the present invention;

FIG. 3 is a cross-sectional view of a stack package according to another exemplary embodiment of the present invention; and

FIGS. 4 to 6 are cross-sectional views of a stack package according to another exemplary embodiment of the present invention.

### DESCRIPTION OF SPECIFIC EMBODIMENTS

Hereinafter, embodiments of the present invention will be described with reference to accompanying drawings. However, the embodiments are for illustrative purposes only and are not intended to limit the scope of the invention.

FIG. 1 is a schematic cross-sectional view of a stack package according to an exemplary embodiment of the present invention.

Referring to FIG. 1, the stack package according to the exemplary embodiment of the present invention includes a substrate 100, a lower semiconductor chip 200, a plurality of upper semiconductor chips 300 having a larger size than the lower semiconductor chip 200, a center via 410 electrically connecting the lower semiconductor chip 200 and the upper semiconductor chips 300, an edge via 420 electrically connecting the plurality of upper semiconductor chips 300, and an edge guide 500 coupling the edge via 420 and the substrate 100.

The substrate 100 may be a package substrate which electrically connects the semiconductor chips inside the package and an external printed circuit board (PCB), or may be a typical PCB; however, the invention is not limited thereto. For example, the substrate 100 may be a plastic substrate or a ceramic substrate. As a specific example, the substrate 100 may be a plastic substrate which includes an epoxy core, an electrical interconnection, and so on.

A semiconductor device, such as a memory device, a logic device, a photoelectric device, or a power device, may be formed as the lower semiconductor chip 200 and the upper semiconductor chips 300. The semiconductor device may include various passive elements, such as a resistor or a capacitor. In addition, the lower semiconductor chip 200 and the upper semiconductor chips 300 may have the same or different type. Meanwhile, although nine upper semiconductor chips 300 are illustrated in FIG. 1, the number of the semiconductor chips may vary.

The center via 410 may include one or more center vias 412, 414, 416 and 418, and may be filled with a conductive material, such as copper, which can electrically connects the lower semiconductor chip 200 and the upper semiconductor chips 300. Meanwhile, although the straight center vias 410 are illustrated in FIG. 1, they may have a stack structure which electrically connects a lower via of the lower semiconductor chip 200 and upper vias of the upper semiconductor chips 300a to 300i. The structure of the edge via 420 and its forming method may be substantially identical to those of the center via 410, and the edge via 420 may electrically connect the plurality of upper semiconductor chips 300 with the exception of the lower semiconductor chip 200. Meanwhile, the center via 410 is named because it is arranged further inside the semiconductor chip than the edge via 410. Thus, the center via 410 need not be arranged at the center of the semiconductor chip. Furthermore, the upper via and the lower via are the general term for through-silicon vias formed in the upper semiconductor chips and the lower semiconductor chip.

The edge guide 500 electrically connects the edge via 420 to the substrate 100. The edge guide 500 may include a horizontal portion 510 formed between the upper semiconductor chips 300, and a vertical portion 520 formed on the substrate 100.

Since the edge guide 500 serves as an electrical path between the edge via 420 and the substrate 100, it may include a conductive material, such as a conductive polymer, a derivative thereof, a metal, or a composite of the conductive polymer and the metal. For example, the edge guide 500 may include one or more material selected from the group consisting of a conductive polymer, such as olyaniline, polythiophene, poly(3,4-ethylene dioxythiophene), polypyrrole, and polyphenylenevinylene (PPV), and a derivative thereof. In addition, the edge guide 500 may include one or more material selected from the group consisting of gold (Au), silver (Ag), copper (Cu), aluminum (Al), nickel (Ni), tungsten (W), titanium (Ti), platinum (Pt), palladium (Pd), tin (Sn), lead (Pb), zinc (Zn), indium (In), cadmium (Cd), chrome (Cr), and molybdenum (Mo). The conductive material may be formed in a monolayer form or a multilayer form. The edge guide 500 may include an insulation material, in addition to the conductive material. For example, the edge guide 500 may include a core portion formed of a conductive material, and an outer portion entirely or partially coating the core portion.

Meanwhile, the stack package according to an exemplary embodiment of the present invention may further include a connection pad 550 formed between the adjacent edge vias of the upper semiconductor chips 300, and electrically connecting the edge vias 420 of the upper semiconductor chip 300 and the edge guide 500. The connection pad 550 may be formed of a conductive material, such as a conductive organic material or a conductive metal; however, the invention is not limited thereto. For example, the connection pad 550 may include one or more material selected from the group consisting of gold (Au), silver (Ag), copper (Cu), aluminum (Al), nickel (Ni), tungsten (W), titanium (Ti), platinum (Pt), palladium (Pd), tin (Sn), lead (Pb), zinc (Zn), indium (In), cadmium (Cd), chrome (Cr), molybdenum (Mo), and an alloy thereof. The metal and the alloy thereof may be formed in a monolayer form or a multilayer form. The connection pad 550 may be a solder bump which electrically and physically connects the upper vias of the upper semiconductor chips 300. That is, the connection pad 550 may be a solder bump which electrically and physically connects the upper semiconductor chips 300, and serves as an electrical connection path with respect to the edge guide 500. Meanwhile, the connection pad 550 and the edge guide 500 may be integrally formed.

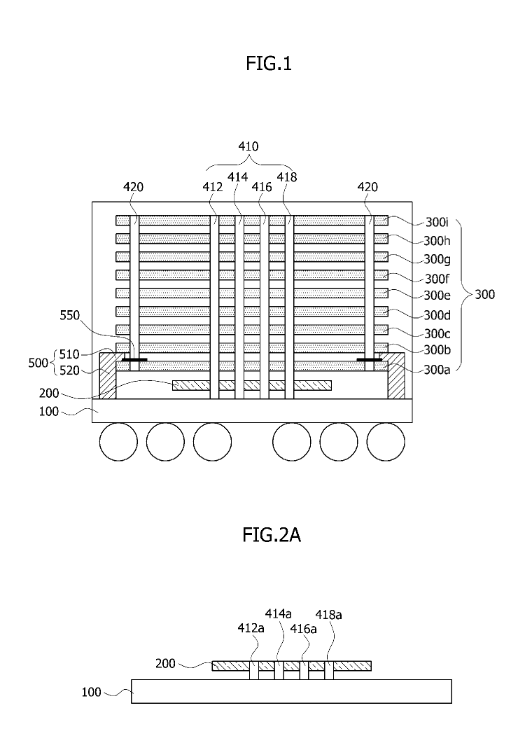

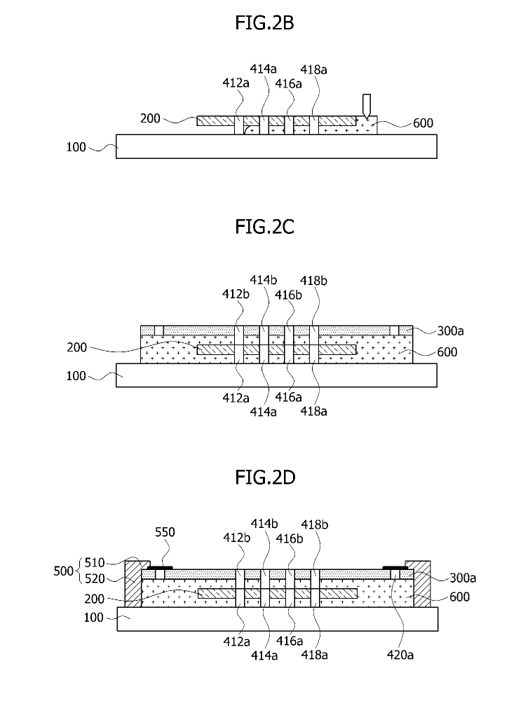

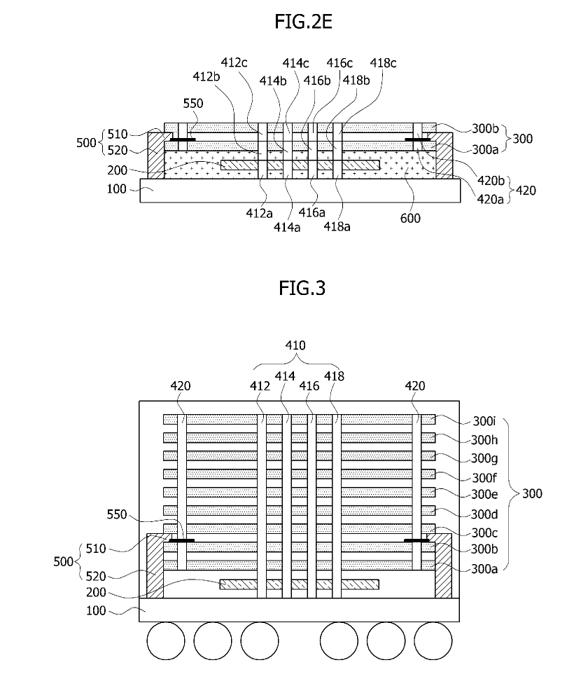

A method for manufacturing a semiconductor chip stack package according to an exemplary embodiment of the present invention will be described below with reference to FIGS. 2A to 2E. Contents overlapped with the foregoing contents will be described briefly or omitted.

Referring to FIG. 2A, a lower semiconductor chip 200 is stacked on a substrate 100. The lower semiconductor chip 200 may include one or more lower vias. In FIG. 2A, four lower vias 412a, 414a, 416a and 418a are exemplarily illustrated. When viewed in the entire package, the vias formed in the lower semiconductor chip 200 may be arranged at the center of the package, as compared to an edge via 420 of an upper semiconductor chip 300.

A semiconductor chip stacking process including a process of forming through-silicon vias (TSVs) of the lower semiconductor chip 200 and upper semiconductor chips 300 may be performed by a known semiconductor chip stacking process. For example, a hole is formed on a semiconductor chip by using a laser drill or a deep reactive ion etching (DRIE) process. Then, a chemical or physical treatment is performed to facilitate the removal of residue, which is generated during the hole formation, and a subsequent plating process, thereby improving a plating attachment property. A seed metal film is formed, and the hole is filled with a conductive material such as copper through an electroplating process, thereby forming a TSV. Alternatively, the hole may be filled with a conductive material through a chemical vapor deposition (CVD) process.

Referring to FIG. 2B, a gap fill process may be performed to fill an empty gap between the lower semiconductor chip 200 and the substrate 100 with a gap filler 600. The gap fill process is performed for reducing stress caused by a difference of a thermal expansion coefficient between the lower semiconductor chip 200 and the substrate 100. In some cases, the gap fill process may be skipped or may be performed at a later step. The gap filler 600 may include a liquid epoxy material and a filler such as silica; however, the invention is not limited thereto. For example, the gap filler 600 may include a thermosetting polymer, such as polyimide, novolak phenol or polynorbonene, and other materials.

Referring to FIG. 2C, a first upper semiconductor chip 300a is stacked on the lower semiconductor chip 200. Upon the stacking of the first upper semiconductor chip 300a, upper vias 412b, 414b, 416b and 418b of the first upper semiconductor chip 300a and the lower vias 412a, 414a, 416a and 418a of the lower semiconductor chip 200 are aligned. The upper vias 412b, 414b, 416b and 418b of the first upper semiconductor chip 300a and the lower vias 412a, 414a, 416a and 418a of the lower semiconductor chip 200 are electrically conducted. Meanwhile, the upper vias 412b, 414b, 416b and 418b of the first upper semiconductor chip 300a and the lower vias 412a, 414a, 416a and 418a of the lower semiconductor chip 200 may be electrically connected through an interconnection material such as a solder.

Next, a gap fill process may be performed to fill a gap between the first upper semiconductor chip 300a and the substrate 100. Also, the gap fill process may be performed to fill a gap between the first upper semiconductor chip 300a and the lower semiconductor chip 200. In some cases, the gap fill process may be skipped or may be performed at a later step. The gap filler 600 may include a liquid epoxy material and a filler such as silica; however, the invention is not limited thereto. For example, the gap filler 600 may include a thermosetting polymer, such as polyimide, novolak phenol or polynorbonene, and other materials.

Referring to FIG. 2D, a connection pad 550 and an edge guide 500 are formed simultaneously or sequentially. The method of forming the connection pad 550 is not specifically limited. For example, the connection pad 550 may be formed by depositing a metal, such as gold, silver, copper, aluminum, tungsten, titanium, or tantalum, through a vacuum deposition process or a sputtering process, and patterning the deposited metal. The connection pad 550 may be formed through a spin coating process, a screen printing process, an electroless plating process, or an electroplating process. In addition, the connection pad 550 may be a solder (solder bump) which physically and electrically connects the first edge via 420a and a second edge via (420b of FIG. 2E) to be stacked later, or a conductive thin film formed separately from the solder.

The edge guide 500 may include a horizontal portion 510 formed between the adjacent upper semiconductor chips, and a vertical portion 520 connecting the horizontal portion 510 to the substrate 100. The horizontal portion 510 and the vertical portion 520 may be integrally formed of the same material by the same method, or may be formed of different materials by different methods. In addition, the connection pad 550 and the edge guide 500 may be integrally formed.

As described above, the edge guide 500 may include a conductive material, such as a conductive polymer, a derivative thereof, a metal, or a composite of a conductive polymer and a metal. The conductive material may be formed with a monolayer or a multilayer. In addition, the edge guide 500 may be formed in various structures. For example, the edge guide 500 may be formed in a structure in which conductive layers are stacked on an insulation layer, or it may be formed in a structure in which an outer surface of a conductive layer is surrounded by an insulation layer. Furthermore, the edge guide 500 may be formed by a thin film deposition process, such as a vacuum deposition process or a sputtering process, a screen printing process, a paste injection process, an electroless plating process, or an electroplating process; however, the invention is not limited thereto. The vertical portion 520 and the horizontal portion 510 may be formed sequentially or simultaneously.

Referring to FIG. 2E, a second upper semiconductor chip 300b is stacked on the first upper semiconductor chip 300a. Here, the first edge via 420a of the first upper semiconductor chip 300a and a second edge via 420b of the second upper semiconductor chip 300b may be coupled to the edge guide 500 through the connection pad 550, and may be electrically connected to the substrate 100 through the vertical portion 520 of the edge guide 500. As described above, the first edge via 420a of the first upper semiconductor chip 300a and the second edge via 420b of the second upper semiconductor chip 300b may be electrically and physically connected through a solder, and the connection pad 550 may be a separate structure which is coupled to the solder, the first edge via 420a, or the second edge via 420b.

In addition, a gap fill process may be performed to fill a gap between the first upper semiconductor chip 300a and the second upper semiconductor chip 300b. Meanwhile, the edge via 420 is the general term for the first edge via 420a and the second edge via 420b existing in each upper semiconductor chip.

Then, the stack package illustrated in FIG. 1 may be implemented by stacking third and fourth upper semiconductor chips on the second upper semiconductor chip 300b. Since subsequent processes are substantially identical to the foregoing processes or are known techniques, a detailed description thereof will be omitted.

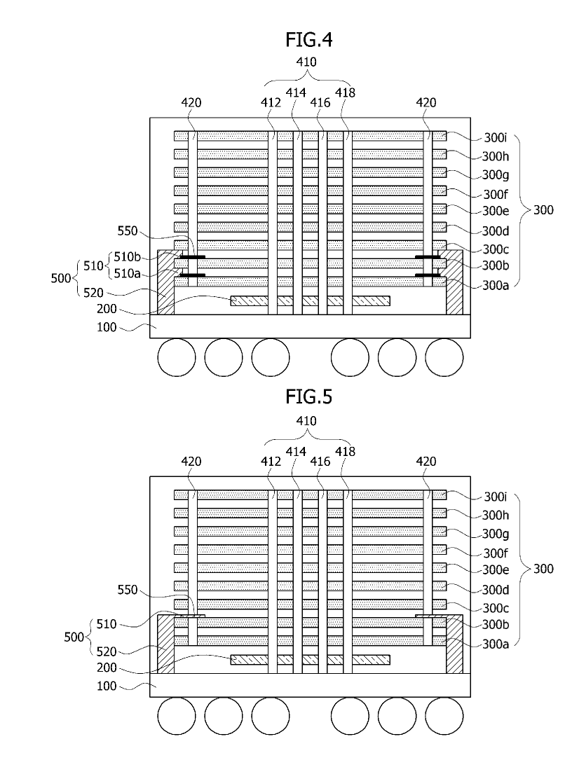

Hereinafter, a stack package according to another exemplary embodiment of the present invention will be described with reference to a cross-sectional view of FIG. 3, and contents overlapped with the foregoing contents will be described briefly or omitted.

Referring to FIG. 3, the edge guide 500 may not be coupled to the edge via 420 between the lowermost upper semiconductor chip 300a and the upper semiconductor chip 300b located just above the lowermost upper semiconductor chip 300a, but coupled to the edge via 420 between other upper semiconductor chips. The edge guide 500 coupled to the edge via 420 between the second upper semiconductor chip 300b and the third upper semiconductor chip 300c is exemplarily illustrated in FIG. 3. Since other contents are substantially identical to those described above, a detailed description thereof will be omitted.

Hereinafter, a stack package according to another exemplary embodiment of the present invention will be described with reference to a cross-sectional view of FIG. 4, and contents overlapped with the foregoing contents will be described briefly or omitted.

Referring to FIG. 4, the edge guide 500 of the stack package according to this exemplary embodiment of the present invention may simultaneously be connected to two or more different points of the edge via 420. FIG. 4 exemplarily illustrates the edge guide 500 having a horizontal portion 510 and a vertical portion 520. The horizontal portion 510 has a first horizontal portion 510a, which is connected to a portion of the edge via between the first upper semiconductor chip 300a and the second upper semiconductor chip 300b, and a second horizontal portion 510b, which is connected to another portion of the edge via between the second upper semiconductor chip 300b and the third upper semiconductor chip 300c. The vertical portion 520 is formed vertically on the substrate 100. Unlike in FIG. 4, the edge guide 500 may couple any two or more points of the edge via 420 of the upper semiconductor chips 300.

Hereinafter, a stack package according to another exemplary embodiment of the present invention will be described with reference to a cross-sectional view of FIG. 5, and contents overlapped with the foregoing contents will be described briefly or omitted.

Referring to FIG. 5, the edge guide 500 of the stack package according to this exemplary embodiment of the present invention may have a horizontal portion 510 and a vertical portion 520. An end of the horizontal portion 510 may be connected to the vertical portion 520, and the other end of the horizontal portion 510 may be directly connected to the edge via 420 of the upper semiconductor chips. That is, the horizontal portion 510 may serve as a connection pad which electrically connects the edge via 420 and the edge guide 500. In addition, the other end of the horizontal portion 510 may serve as an interconnection, such as solder, which physically and electrically connects the edge vias 420 of each upper semiconductor chip. Here, the horizontal portion 510 may include an interconnection material such as a solder.

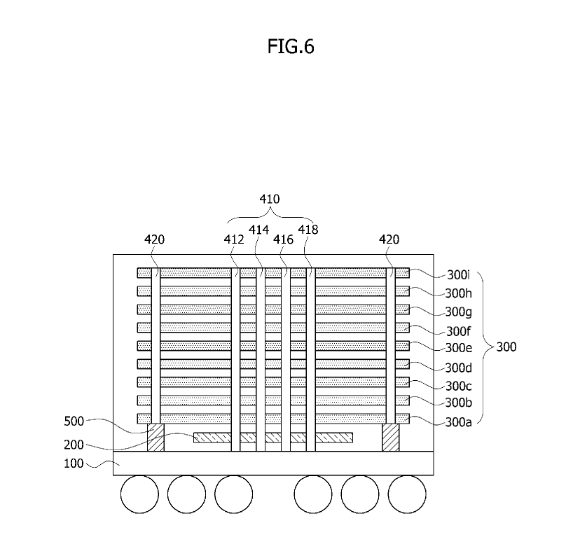

Hereinafter, a stack package according to another exemplary embodiment of the present invention will be described with reference to a cross-sectional view of FIG. 6, and contents overlapped with the foregoing contents will be described briefly or omitted.

Referring to FIG. 6, the edge guide 500 of the semiconductor chip stack package according to this exemplary embodiment of the present invention may be directly connected to the substrate 100 from the edge via 420 of the first upper semiconductor chip 300a, which is the lowermost upper semiconductor chip among the upper semiconductor chips 300. Here, the edge guide 500 may have a vertical shape. Since the edge guide 500 serves as an electrical path between the edge via 420 and the substrate 100, it may include a conductive material, such as a conductive polymer, a derivative thereof, a metal, or a composite of a conductive polymer and a metal.

For example, the edge guide 500 may include one or more material selected from the group consisting of a conductive polymer, such as olyaniline, polythiophene, poly(3,4-ethylene dioxythiophene), polypyrrole, and polyphenylenevinylene (PPV), and a derivative thereof. In addition, the edge guide 500 may include one or more material selected from the group consisting of gold (Au), silver (Ag), copper (Cu), aluminum (Al), nickel (Ni), tungsten (W), titanium (Ti), platinum (Pt), palladium (Pd), tin (Sn), lead (Pb), zinc (Zn), indium (In), cadmium (Cd), chrome (Cr), molybdenum (Mo), and an alloy thereof. The edge guide 500 may include an insulation material, in addition to the conductive material. The conductive material may be formed with a monolayer or a multilayer.

In addition, the edge guide 500 may be formed in various structures. For example, the edge guide 500 may be formed in a structure in which conductive layers are stacked on an insulation layer, or it may be formed in a structure in which an outer surface of a conductive layer is surrounded by an insulation layer. Furthermore, the edge guide 500 may be formed by a thin film deposition process, such as a vacuum deposition process or a sputtering process, a screen printing process, a paste injection process, an electroless plating process, or an electroplating process; however, the invention is not limited thereto.

Although not illustrated, an interconnection layer formed of a material such as a solder may be further formed at the lower portion of the edge via 420 and the upper portion of the edge guide 500, that is, the interface where the edge via 420 and the edge guide 500 are contacted with each other.

The exemplary embodiments of the present invention have been disclosed above for illustrative purposes. Those skilled in the art will appreciate that various modifications, additions and substitutions are possible, without departing from the scope and spirit of the invention as disclosed in the accompanying claims.

What is claimed is:

1. A stack package comprising:
a substrate;
a lower semiconductor chip stacked on the substrate and electrically connected to the substrate through a lower via;
a plurality of upper semiconductor chips stacked on the lower semiconductor chip and electrically connected to the lower via through an upper via, wherein the upper semiconductor chips are larger in size than the lower semiconductor chip; and
an edge guide electrically connecting edge vias of the upper semiconductor chips and the substrate.

2. The stack package of claim 1, further comprising a connection pad formed between the adjacent edge vias of the upper semiconductor chips, and electrically connecting the edge vias of the upper semiconductor chips and the edge guide.

3. The stack package of claim 2, wherein the edge guide and the connection pad are integrally formed.

4. The stack package of claim 1, wherein the edge guide comprises:
a horizontal portion formed between the adjacent upper semiconductor chips; and
a vertical portion connecting the horizontal portion to the substrate.

5. The stack package of claim 4, wherein the horizontal portion of the edge guide comprises an interconnection material which connects the edge vias of the upper semiconductor chips.

6. The stack package of claim 1, wherein the edge guide couples the substrate and the bottom of the edge via of the lowermost upper semiconductor chip among the upper semiconductor chips.

7. The stack package of claim 1, wherein the edge guide comprises one or more material selected from the group consisting of gold (Au), silver (Ag), copper (Cu), aluminum (Al), nickel (Ni), tungsten (W), titanium (Ti), platinum (Pt), palladium (Pd), tin (Sn), lead (Pb), zinc (Zn), indium (In), cadmium (Cd), chrome (Cr), molybdenum (Mo), and an alloy thereof.

8. The stack package of claim 1, wherein the edge guide simultaneously couples two or more different positions of the edge vias of the upper semiconductor chips.

9. The stack package of claim 1, wherein the edge guide is electrically connected to the edge via through a solder.

10. A method for manufacturing a stack package, the method comprising:
stacking a lower semiconductor chip on a substrate, wherein the lower semiconductor chip is electrically connected to the substrate through a lower via;
stacking upper semiconductor chips on the lower semiconductor chip, wherein the upper semiconductor chips are larger in size than the lower semiconductor chip and are electrically connected to the lower via through an upper via; and
forming an edge guide which electrically connects edge vias of the upper semiconductor chips and the substrate.

11. The method of claim 10, further comprising, forming a connection pad between the adjacent edge vias of the upper semiconductor chips and electrically connect the edge vias of the upper semiconductor chips and the edge guide.

12. The method of claim 11, wherein the edge guide and the connection pad are integrally formed.

13. The method of claim 10, wherein the edge guide comprises:
a horizontal portion formed between the adjacent upper semiconductor chips; and
a vertical portion connecting the horizontal portion to the substrate.

14. The method of claim 10, wherein the edge guide couples the substrate and the bottom of the edge via of the lowermost upper semiconductor chip among the upper semiconductor chips.

15. The method of claim 10, wherein the edge guide simultaneously couples two or more different positions of the edge vias of the upper semiconductor chips.

16. The method of claim 10, further comprising filling a gap between the lower semiconductor chip and the substrate after the lower semiconductor chip is stacked on the substrate.

17. The method of claim 10, wherein the edge guide comprises one or more material selected from the group consisting of gold (Au), silver (Ag), copper (Cu), aluminum (Al), nickel (Ni), tungsten (W), titanium (Ti), platinum (Pt), palladium (Pd), tin (Sn), lead (Pb), zinc (Zn), indium (In), cadmium (Cd), chrome (Cr), molybdenum (Mo), and an alloy thereof.

18. The method of claim 10, wherein the edge guide is electrically connect to the edge via through a solder.
